(19) United States
(12) Patent Application Publication
(10) Pub. No.: US 2024/0178117 A1
(43) Pub. Date: May 30, 2024

(54) SEMICONDUCTOR PACKAGES

(71) Applicant: SAMSUNG ELECTRONICS CO., LTD., Suwon-si (KR)

(72) Inventor: Myung Sam KANG, Suwon-si (KR)

(21) Appl. No.: 18/468,992

(22) Filed: Sep. 18, 2023

(30) Foreign Application Priority Data
Nov. 30, 2022 (KR) 10-2022-0164335

(51) Int. Cl. H01L 23/498; H01L 23/00; H01L 23/15; H01L 25/065

(52) U.S. Cl. CPC H01L 23/49822; H01L 23/15; H01L 23/49816; H01L 24/08; H01L 24/16; H01L 25/0655; H01L 2224/08146; H01L 2224/08165; H01L 2224/16227; H01L 2924/01029; H01L 2924/1433; H01L 2924/1435

(57) ABSTRACT

A semiconductor package comprises a first redistribution layer including a first conductive pattern; a connection module on an upper surface of the first redistribution layer; a glass core extending around the connection module on the upper surface of the first redistribution layer; a through via extended in the glass core; a second insulating layer on the glass core, wherein a portion of the second insulating layer is in the through via; a second redistribution layer on an upper surface of the glass core, wherein the second redistribution layer includes a via pad; and a first semiconductor chip and a second semiconductor chip space apart from each other on an upper surface of the second redistribution layer, wherein the via pad is in contact with the through via, and wherein the first semiconductor chip and the second semiconductor chip are electrically connected to each other through the connection module.

### CROSS-REFERENCE TO RELATED APPLICATION

This application claims priority to Korean Patent Application No. 10-2022-0164335 filed on Nov. 30, 2022 in the Korean Intellectual Property Office and all the benefits accruing therefrom under 35 U.S.C. 119, the contents of which in its entirety are herein incorporated by reference.

### BACKGROUND

The present disclosure relates to semiconductor packages, and more particularly, to semiconductor packages comprising semiconductor chips and a connection module connecting the semiconductor chips.

With the development of electronic industry, demands for high functionality, high-speed, and miniaturization of electronic components have been increased. In response to this trend, a method of stacking and packaging various semiconductor chips on one package substrate or a method of stacking a package on another package may be used. For example, a package-in-package (PIP) type semiconductor package, a package-on-package (POP) type semiconductor package, or a 2.5D semiconductor package may be used.

The 2.5D semiconductor package may include an interposer for electrical connection between an upper semiconductor chip and a lower package. As the semiconductor package is miniaturized, it is becoming important to reduce warpage of the interposer.

### SUMMARY

The present disclosure may provide a semiconductor package in which warpage is reduced.

The present disclosure are not limited to those mentioned above and additional aspects of the present disclosure, which are not mentioned herein, will be clearly understood by those skilled in the art from the following description of the present disclosure.

According to some embodiments of the present disclosure, there is provided a semiconductor package comprising: a first redistribution layer that includes a first insulating layer and a first conductive pattern in the first insulating layer; a connection module on an upper surface of the first redistribution layer; a glass core that extends around the connection module on the upper surface of the first redistribution layer; a through via extended in the glass core; a second insulating layer on the glass core, wherein a portion of the second insulating layer is in the through via; a second redistribution layer on an upper surface of the glass core, wherein the second redistribution layer includes a third insulating layer, a second conductive pattern, and a via pad, and wherein the second conductive pattern and the via pad are in the third insulating layer; and a first semiconductor chip and a second semiconductor chip on an upper surface of the second redistribution layer, wherein the first semiconductor chip and the second semiconductor chip are spaced apart from each other, wherein the via pad is in contact with the through via, and wherein the first semiconductor chip and the second semiconductor chip are electrically connected to each other through the connection module.

According to some embodiments of the present disclosure, there is provided a semiconductor package comprising: a first redistribution layer that includes a first insulating layer and a first conductive pattern in the first insulating layer; a glass core on an upper surface of the first redistribution layer; a connection module in the glass core; a second insulating layer that extend around the glass core; a second redistribution layer on an upper surface of the glass core, wherein the second redistribution layer includes a third insulating layer, a second conductive pattern, and a via pad, and wherein the second conductive pattern and the via pad are in the third insulating layer; a through via that extends through the glass core in a vertical direction perpendicular to the upper surface of the first redistribution layer, wherein the first redistribution layer and the second redistribution layer are electrically connected to each other through the through via; and a first semiconductor chip and a second semiconductor chip on an upper surface of the second redistribution layer and spaced apart from each other, wherein the first semiconductor chip and the second semiconductor chip are electrically connected through the connection module, wherein the through via includes a lower contact portion on a lower surface of the glass core and an upper contact portion that is in contact with the via pad, and wherein a width of the lower contact portion in a horizontal direction parallel with the upper surface of the first redistribution layer is greater than a width of the upper contact portion in the horizontal direction.

According to some embodiments of the present disclosure, there is provided a semiconductor package comprising: a first redistribution layer that includes a first insulating layer and a first conductive pattern in the first insulating layer; a connection module on an upper surface of the first redistribution layer; a glass core that extends around the connection module on the upper surface of the first redistribution layer, wherein the glass core includes a through via; a second insulating layer that extend around the glass core, wherein a portion of the second insulating layer is inside the through via; a second redistribution layer on an upper surface of the glass core, wherein the second redistribution layer includes a third insulating layer, a second conductive pattern, and a via pad, and wherein the second conductive pattern and the via pad are in the third insulating layer; and a first semiconductor chip and a second semiconductor chip that are spaced apart from each other on an upper surface of the second redistribution layer, wherein the via pad is in contact with an upper contact portion of the through via, wherein the via pad includes a metal layer, wherein the first semiconductor chip and the second semiconductor chip are electrically connected to each other through the connection module, wherein the through via includes a lower contact portion that is electrically connected to the first conductive pattern, and wherein a width of the lower contact portion in a horizontal direction parallel with the upper surface of the first redistribution layer is greater than a width of the upper contact portion in the horizontal direction.

### BRIEF DESCRIPTION OF THE DRAWINGS

The above and other aspects and features of the present disclosure will become more apparent by describing in detail example embodiments thereof with reference to the attached drawings, in which:

FIG. 1 is an example plan view illustrating a semiconductor package according to some embodiments.

FIG. 2 is an example cross-sectional view taken along line A-A′ of FIG. 1.

FIG. 3 is an enlarged view illustrating a portion R1 of FIG. 2.

FIG. 4 is an exploded perspective view illustrating a through via and a via pad of a semiconductor package according to some embodiments.

FIGS. 5 and 6 are enlarged views illustrating a portion R2 of FIG. 2

FIG. 7 is a cross-sectional view illustrating a semiconductor package according to some embodiments.

FIG. 8 is an enlarged view illustrating a portion R3 of FIG. 7.

FIGS. 9 and 10 are enlarged views illustrating a portion R4 of FIG. 7.

FIG. 11 is a cross-sectional view illustrating a semiconductor package according to some embodiments.

FIG. 12 is a view illustrating an electronic device according to some embodiments.

FIG. 13 is a view illustrating an electronic device according to some embodiments.

FIG. 14 is a cross-sectional view illustrating a semiconductor package and a main board of FIG. 13.

FIGS. 15 to 24 are views illustrating intermediate steps to describe a method of manufacturing a semiconductor package according to some embodiments.

### DETAILED DESCRIPTION OF THE DISCLOSURE

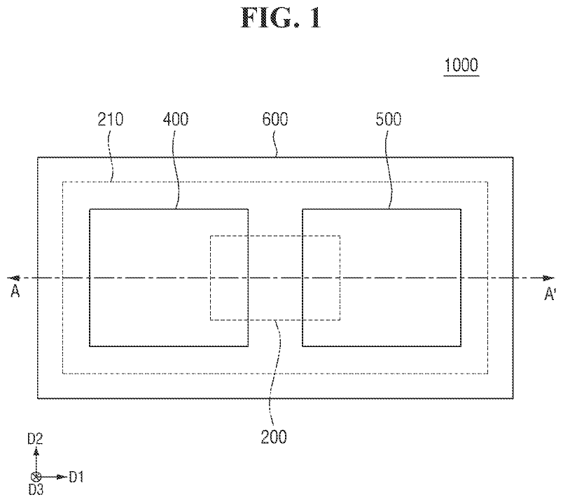

Hereinafter, a semiconductor package according to some embodiments will be described with reference to FIGS. 1 to 6. In FIGS. 1 to 6, the semiconductor package according to some embodiments may be a semiconductor package that includes a connection module connecting semiconductor chips therein, but this is only an example and the embodiments of the present disclosure are not limited thereto.

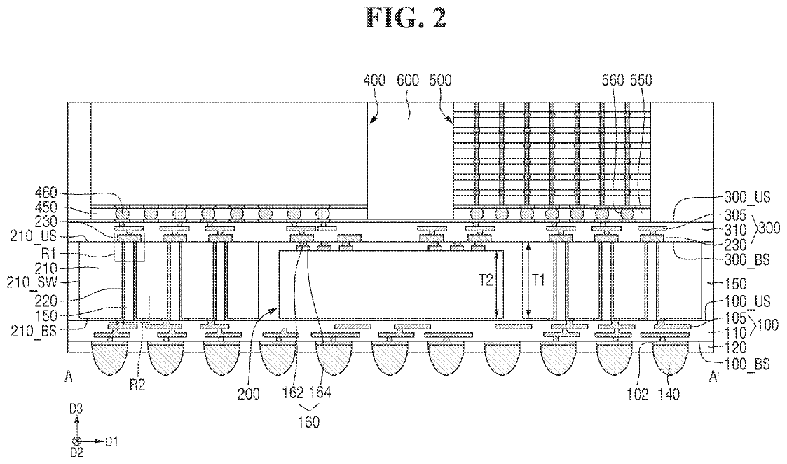

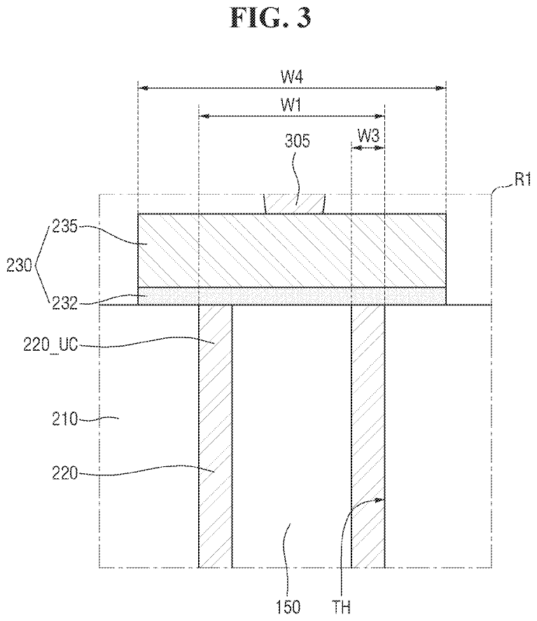

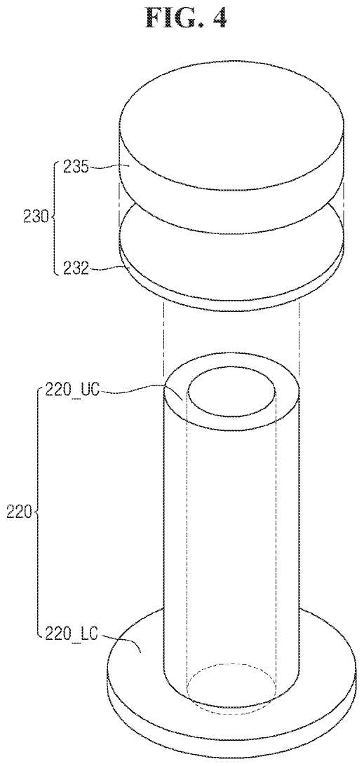

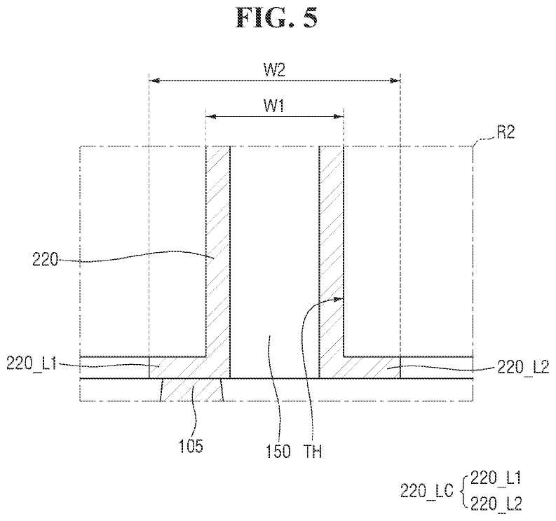

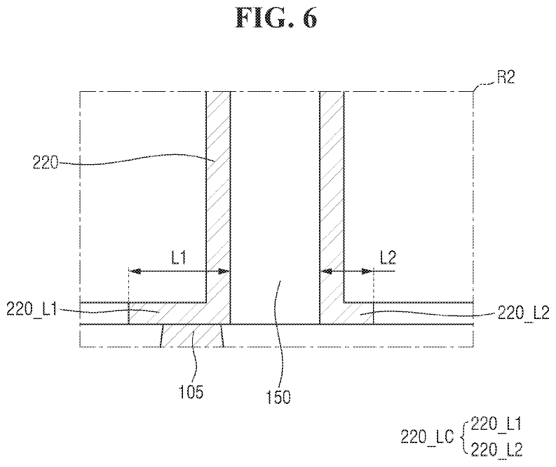

FIG. 1 is an example plan view illustrating a semiconductor package according to some embodiments. FIG. 2 is an example cross-sectional view taken along line A-A′ of FIG. 1. FIG. 3 is an enlarged view illustrating a portion R1 of FIG. 2. FIG. 4 is an exploded perspective view illustrating a through via and a via pad of a semiconductor package according to some embodiments. FIGS. 5 and 6 are enlarged views illustrating a portion R2 of FIG. 2.

Referring to FIGS. 1 and 2, a semiconductor package 1000 according to some embodiments may include a first redistribution layer 100, a connection module 200, a glass core 210, a second insulating layer 150, a second redistribution layer 300, a first semiconductor chip 400, a second semiconductor chip 500, and a mold layer 600.

The first semiconductor chip 400 and the second semiconductor chip 500 may be spaced apart from each other in a first direction D1. In the present disclosure, the first direction D1, a second direction D2, and a third direction D3 may intersect one another. The first direction D1, the second direction D2, and the third direction D3 may be perpendicular or substantially perpendicular to one another. In FIG. 1, each of the first semiconductor chip 400 and the second semiconductor chip 500 is illustrated as being a single chip, but is not limited thereto. For example, the semiconductor package 1000 according to some embodiments may include one first semiconductor chip 400 and a plurality of second semiconductor chips 500. The semiconductor package 1000 according to other embodiments may include a plurality of first semiconductor chips 400 and a plurality of second semiconductor chips 500.

The first redistribution layer 100 may include a first insulating layer 110 and a first conductive pattern 105. The first redistribution layer 100 may include an upper surface 100_US and a lower surface 100_BS, which are opposite to each other. The first direction D1 and the second direction D2 may be parallel with the upper surface 100_US of the first redistribution layer 100. The third direction D3 may be perpendicular to the upper surface 100_US of the first redistribution layer 100.

The first conductive pattern 105 may be formed in the first insulating layer 110. The first insulating layer 110 and the first conductive pattern 115 may constitute a wiring pattern for electrically connecting a first lower pad 102 on the lower surface 100_BS of the first redistribution layer 100 with a through via 220 on the upper surface 100_US of the first redistribution layer 100.

The first insulating layer 110 is illustrated as a single layer, but this is only for convenience of description. For example, the first insulating layer 110 may be composed of multiple layers to form the first conductive pattern 105 of multiple layers.

The first insulating layer 110 may include an insulating material. For example, the first insulating layer 110 may include an epoxy resin and/or a polyimide resin, but is not limited thereto. The first conductive pattern 105 may include, for example, a metal material such as copper (Cu), aluminum (Al), silver (Ag), tin (Sn), gold (Au), nickel (Ni), lead (Pb), titanium (Ti) and/or their alloy.

A first lower passivation layer 120 and the first lower pad 102 may be formed on the lower surface 100_BS of the first redistribution layer 100. The first lower pad 102 may be electrically connected to the first conductive pattern 105. The first lower passivation layer 120 may cover at least a portion of the lower surface 100_BS of the first redistribution layer 100, and may expose a portion of the first lower pad 102.

The first lower passivation layer 120 may include, for example, a photoimageable dielectric (PID) material, but is not limited thereto. The first lower pad 102 may include, for example, a metal material such as copper (Cu) or aluminum (Al), but is not limited thereto.

In some embodiments, a first connection member 140 may be formed on the lower surface 100_BS of the first redistribution layer 100. In detail, the first connection member 140 may be on the first lower pad 102.

The first connection member 140 may electrically connect a circuit board with the semiconductor package 1000. The circuit board may be a package substrate. The circuit board may be a printed circuit board (PCB), but is not limited thereto. Therefore, the first connection member 140 may provide an electrical signal from an external device to the first redistribution layer 100 or may provide an electrical signal from the first redistribution layer 100 to the external device. As used herein, the terms “external/outside device” or “external/outside signal” are intended to broadly refer to a device, circuit, block, module and/or signal that resides externally (i.e., outside of a functional or physical boundary) with respect to a given circuit, block, module, or device.

The first connection member 140 may be a solder bump that includes a low melting point metal such as tin (Sn) and a tin (Sn) alloy, but is not limited thereto. The first connection member 140 may have various shapes such as a land, a ball, a pin, and a pillar. The first connection member 140 may be formed of a single layer or multiple layers. When the first connection member 140 is formed of a single layer, the first connection member 140 may include, for example, a tin-silver (Sn—Ag) solder or copper (Cu). When the first connection member 140 is formed of multiple layers, the first connection member 140 may include, for example, a copper (Cu) filler and a solder. Various modifications may be made in the number, interval, arrangement shape, etc. of the first connection member 140 depending on the design.

Referring to FIGS. 2 and 3, a through hole TH and a through via 220 may be disposed in the glass core 210.

The glass core 210 may be disposed on the upper surface 100_US of the first redistribution layer 100. A lower surface 210_BS of the glass core 210 may be spaced apart from the upper surface 100_US of the first redistribution layer 100. In some embodiments, a portion of the through via 220 may be disposed between the glass core 210 and the first redistribution layer 100. The upper surface 210_US of the glass core 210 may be in contact with a lower surface 300_BS of the second redistribution layer 300.

The through hole TH may extend through (e.g., pass through) the glass core 210 in the third direction D3. The through hole TH may have, for example, a cylindrical shape, but is not limited thereto. The through via 220 may be formed along an inner wall (e.g., an inner sidewall) of the through hole TH. That is, the through via 220 may extend in (e.g., pass through) the glass core 210 in the third direction D3. A via pad 230 may be disposed on the glass core 210. The via pad 230 may be in contact with the through via 220. Therefore, the through via 220 may (e.g., electrically) connect the first redistribution layer 100 with the via pad 230. The first and second semiconductor chips 400 and 500 may be electrically connected with the second redistribution layer 300 and the first redistribution layer 100 through the through via 220. The through via 220 may include a metal material such as copper (Cu) or aluminum (Al), but is not limited thereto.

Referring to FIGS. 3 and 4, the through via 220 may include an upper contact portion 220_UC and a lower contact portion 220_LC. The upper contact portion 220_UC may be a portion of the through via 220 disposed above the lower surface 210_BS of the glass core 210. The lower contact portion 220_LC may be a portion of the through via 220 disposed below the lower surface 210_BS of the glass core 210. The upper contact portion 220_UC and the lower contact portion 220_LC may be connected to each other such that the through via 220 has a unitary structure. In some embodiments, the upper contact portion 220_UC of the through via 220 may be in the shape of a cylinder having an inner hole (e.g., at the center thereof), but is not limited thereto. The lower contact portion 220_LC of the through via 220 may have a donut shape that includes an inner hole (e.g., at the center thereof), but is not limited thereto. The inner hole of the upper contact portion 220_UC and the inner hole of the lower contact portion 220_LC may be connected to each other, overlapped, and/or a unitary inner hole. For example, the inner hole of the upper contact portion 220_UC may be a remaining portion of the through hole TH after forming the through via 220. In some embodiments, a second width W2 (Referring to FIG. 5) of the lower contact portion 220_LC in a direction parallel with the upper surface 100_US of the first redistribution layer 100 (e.g., the first direction D1) may be greater than a width of the upper contact portion 220_UC in the direction parallel with the upper surface 100_US of the first redistribution layer 100. The width of the upper contact portion 220_UC may be the same as a first width W1 of the through hole TH in the direction parallel with the upper surface 100_US of the first redistribution layer 100. The first width W1 may include a width of the inner hole of the upper contact portion 220_UC. The second width W2 may include a width of the inner hole of the lower contact portion 220_LC. The width of the inner hole of the upper contact portion 220_UC may be the same as the width of the inner hole of the lower contact portion 220_LC.

The upper contact portion 220_UC of the through via 220 may be in contact with the via pad 230. The via pad 230 may completely overlap (e.g., cover) the through hole TH in the third direction D3. In other words, the upper contact portion 220_UC may be completely overlapped by the via pad 230 in the third direction D3. In some embodiments, a fourth width W4 of the via pad 230 in the direction parallel with the upper surface 100_US of the first redistribution layer 100 may be greater than the first width W1 of the through hole TH, but the embodiments of the present disclosure are not limited thereto. For example, the first width W1 of the through hole TH and the fourth width W4 of the via pad 230 may be the same as each other. The first width W1 of the through hole TH may be (about) 60 micrometers (μm) or less.

The through via 220 may be formed along the inner wall (e.g., inner sidewalls) of the through hole TH and may include an inner hole (e.g., at the center thereof). The inner hole may be the remaining portion of the through hole TH after the formation of the through via 220 on the inner wall of the through hole TH. In some embodiments, the second insulating layer 150 may be disposed on an inner sidewall of the through via 220. For example, the second insulating layer 150 may be filled in the inner hole. A width W3 of the through via 220 (e.g., a thickness of the through via 220 on the inner sidewall of the through hole TH) in the direction parallel with the upper surface 100_US of the first redistribution layer 100 may be (about) 20 μm or less. For example, a distance between an outer side surface of the through via 220 and an outer side surface of the second insulating layer 150 disposed inside of the through via 220 in the first direction D1 may be (about) 20 μm or less

The via pad 230 may include a seed layer 232 and a metal layer 235. In detail, the upper contact portion 220_UC may be in contact with the seed layer 232. The seed layer 232 may include titanium (Ti), copper (Cu), or the like, but is not limited thereto. The seed layer 232 is illustrated as a single layer, but is not limited thereto. For example, the seed layer 232 may be formed of a plurality of layers. When the seed layer 232 is formed of two layers, the first layer may include titanium (Ti), and the second layer may include titanium (Ti) and copper (Cu), but the embodiments of the first and second layers are not limited thereto.

The metal layer 235 may be formed on the seed layer 232. The metal layer 235 may include a metal material such as copper (Cu) or aluminum (Al), but is not limited thereto. The seed layer 232 may be omitted.

Referring to FIG. 5, the lower contact portion 220_LC of the through via 220 may be disposed on the lower surface 210_BS of the glass core 210.

The lower contact portion 220_LC may be in contact with the first conductive pattern 105. The lower contact portion 220_LC may include a first portion 220_L1 and a second portion 220_L2. The first portion 220_L1 may include an area that is in contact with the first conductive pattern 105. The lower contact portion 220_LC may be electrically connected with the first conductive pattern 105. The second portion 220 L2 may not include an area that is in contact with the first conductive pattern 105. The first portion 220_L1 may be on the substantially opposite side of the second portion 220_L2 relative to the through hole TH in a cross-sectional view. For example, a portion of the second insulating layer 150 may be between the first portion 220_L1 and the second portion 220_L2 in a cross-sectional view. In some embodiments, a width of the first portion 220_L1 in a direction parallel with the upper surface 100_US of the first redistribution layer 100 (e.g., the first direction D1) and a width of the second portion 220_L2 in the direction parallel with the upper surface 100_US of the first redistribution layer 100 may be the same as each other. For example, the width of the first portion 220_L1 and the width of the second portion 220_L2 in the first direction D1 may be the same as each other.

Referring to FIG. 6, the first portion 220_L1 may have a first portion width L1 in a direction parallel with the upper surface 100_US of the first redistribution layer 100 (e.g., the first direction D1), and the second portion 220_L2 may have a second portion width L2 in the direction parallel with the upper surface 100_US of the first redistribution layer 100. In some embodiments, the first portion width L1 may be greater than the second portion width L2. The first portion width L1 may be greater than a width of the first conductive pattern 105 that is in contact with the lower contact portion 220_LC in the direction parallel with the upper surface 100_US of the first redistribution layer 100. In this case, a contact area between the lower contact portion 220_LC and the first conductive pattern 105 may be increased.

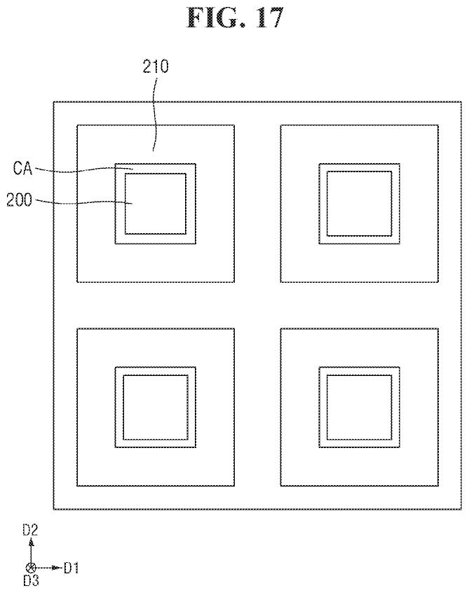

Referring back to FIG. 2, the connection module 200 may be on the upper surface 100_US of the first redistribution layer 100. The glass core 210 may extend around (e.g., surround) the connection module 200. In other words, the glass core 210 may include a cavity (CA of FIG. 17), and the connection module 200 may be disposed in the cavity CA.

The glass core 210 may have a first thickness T1 in the third direction D3. The connection module 200 may have a second thickness T2 in the third direction D3. In some embodiments, the first thickness T1 may be greater than the second thickness T2. When the first thickness T1 is greater than the second thickness T2, a difference between the first thickness T1 and the second thickness T2 may be (about) 15 μm to 30 μm, but the embodiments of the present disclosure are not limited thereto. For example, the first thickness T1 and the second thickness T2 may be the same as each other.

The connection module 200 may connect a semiconductor chip with another semiconductor chip. The connection module 200 may include silicon (Si), but is not limited thereto. The connection module 200 may be, for example, a silicon-bridge that includes a conductive pattern therein, but is not limited thereto. For example, the connection module 200 may be a passive element that includes a capacitor or an inductor.

The glass core 210 may include, for example, glass, but is not limited thereto. Coefficient of Thermal expansion (CTE) of the glass core 210 may be substantially the same as CTE of the connection module 200. In the present disclosure, “substantially the same CTE” may mean a difference within +/−5%. For example, the difference between the CTE of the glass core 210 and the CTE of the connection module 200 may be in the range of −5% to +5%. As the CTE of the glass core 210 and the CTE of the connection module 200 are substantially the same as each other, warpage of the semiconductor package 1000 may be reduced.

A first bump 160 may be disposed on the connection module 200. The first bump 160 may electrically connect the connection module 200 with the first and second semiconductor chips 400 and 500. That is, the connection module 200 may transfer an electrical signal between the first semiconductor chip 400 and the second semiconductor chip 500.

The first bump 160 may include, for example, a first pillar layer 164 and a first solder layer 162.

The first pillar layer 164 may be protruded from the connection module 200. The first pillar layer 164 may include, for example, copper (Cu), a copper alloy, nickel (Ni), a nickel alloy, palladium (Pd), platinum (Pt), gold (Au), cobalt (Co) or their combination, but is not limited thereto.

The first solder layer 162 may connect the first pillar layer 164 with the second redistribution layer 300. For example, the first solder layer 162 may be (electrically) connected to a portion of the second conductive patterns 305. The first solder layer 162 may be connected (e.g., electrically connected) to a portion of the via pad 230. The first solder layer 162 may be, for example, spherical or elliptical, but is not limited thereto. The first solder layer 162 may include, for example, tin (Sn), indium (In), bismuth (Bi), antimony (Sb), copper (Cu), silver (Ag), zinc (Zn), lead (Pb), or their combination, but is not limited thereto.

The second insulating layer 150 may be disposed on the upper surface 100_US of the first redistribution layer 100. In some embodiments, the second insulating layer 150 may be disposed on the connection module 200, the first bump 160, and/or the glass core 210. For example, the second insulating layer 150 may fill a remaining portion of the connection module 200 disposed on the cavity CA of the glass core 210. In some embodiments, the second insulating layer 150 may extend around (e.g., surround) the connection module 200 and the first bump 160.

In some embodiments, the second insulating layer 150 may extend around (e.g., surround) the glass core 210. For example, the second insulating layer 150 may be on (e.g., cover) a sidewall 210_SW of the glass core 210. The sidewall 210_SW of the glass core 210 may not be exposed from the second insulating layer 150.

In some embodiments, the second insulating layer 150 may be disposed inside (e.g., on an inner sidewall of) the through via 220. For example, the second insulating layer 150 may fill the inner holes of the upper contact portion 220_UC and the lower contact portion 220_LC. The first width W1 may include a width of the second insulating layer 150. The second width W2 may include the width of the second insulating layer 150. The second insulating layer 150 may be simultaneously formed inside the through via 220 and on the glass core 210, and its upper surface may be planarized by a grinding process.

The second insulating layer 150 may include an insulating material. For example, the second insulating layer 150 may include an epoxy resin and/or a polyimide resin, but is not limited thereto.

The second redistribution layer 300 may be disposed on the upper surface 210_US of the glass core 210. The second redistribution layer 300 may include a third insulating layer 310, a via pad 230, and a second conductive pattern 305.

The second conductive pattern 305 and the via pad 230 may be formed in the third insulating layer 310. The via pad 230 may be electrically connected to the second conductive pattern 305. The second conductive pattern 305 and the via pad 230 may constitute a wiring pattern for electrically connecting the through via 220 with the first and second semiconductor chips 400 and 500.

The third insulating layer 310 is illustrated as a single layer, but this is only for convenience of description. For example, the third insulating layer 310 may be composed of multiple layers to form the second conductive pattern 305 of multiple layers.

The third insulating layer 310 may include an insulating material. For example, the third insulating layer 310 may include an epoxy resin and/or a polyimide resin, but is not limited thereto. The second conductive pattern 305 may include, for example, a metal material that includes copper (Cu), aluminum (Al), silver (Ag), tin (Sn), gold (Au), nickel (Ni), lead (Pb), titanium (Ti) or their alloy, but is not limited thereto.

The first semiconductor chip 400 and the second semiconductor chip 500 may be spaced apart from each other in the first direction D1 and disposed on an upper surface 300_US of the second redistribution layer 300. Each of the first semiconductor chip 400 and the second semiconductor chip 500 may be an integrated circuit IC in which, for example, hundreds to millions of semiconductor elements are integrated in one chip.

In some embodiments, the first semiconductor chip 400 may be a logic semiconductor chip. For example, the first semiconductor chip 400 may be an application processor (AP), a Central Processing Unit (CPU), a Graphic Processing Unit (GPU), a Field Programmable Gate Array (FPGA), a digital signal processor, an encryption processor, a microprocessor, a microcontroller, and an application-specific IC (ASIC), but is not limited thereto.

In some embodiments, the second semiconductor chip 500 may be a memory semiconductor chip. For example, the second semiconductor chip 500 may be a volatile memory such as a dynamic random access memory (DRAM) or a static random access memory (SRAM) or may be a non-volatile memory such as a flash memory, a phase-change random access memory (PRAM), a magnetoresistive random access memory (MRAM), a ferroelectric random access memory (FeRAM), or a resistive random access memory (RRAM).

For example, the first semiconductor chip 400 may be an ASIC such as a GPU, and the second semiconductor chip 500 may be a stack memory such as a high bandwidth memory (HBM). The stack memory may have a shape in which a plurality of integrated circuits are stacked. The stacked integrated circuits may be electrically connected to each other through a through silicon via (TSV) or the like.

Each of the first semiconductor chip 400 and the second semiconductor chip 500 may include a chip pad. The chip pad may be exposed from a lower surface of each of the first semiconductor chip 400 and the second semiconductor chip 500. The chip pad may be used to electrically connect each of the first semiconductor chip 400 and the second semiconductor chip 500 to other components. The chip pad may include, but is not limited to, a metal material such as copper (Cu) or aluminum (Al).

The first semiconductor chip 400 and the second semiconductor chip 500 may be packaged on the upper surface 300_US of the second redistribution layer 300. For example, a second connection member 460 may be formed between the second redistribution layer 300 and the first semiconductor chip 400. The second connection member 460 may electrically connect the second redistribution layer 300 with the first semiconductor chip 400.

In addition, for example, a third connection member 560 may be formed between the second redistribution layer 300 and the second semiconductor chip 500. The third connection member 560 may electrically connect the second redistribution layer 300 with the second semiconductor chip 500.

In some embodiments, a size of the second connection member 460 may be smaller than that of the first connection member 140. For example, a width of the second connection member 460 in the first direction D1 may be smaller than that of the first connection member 140 in the first direction D1. The width of the second connection member 460 in the second direction D2 may be smaller than that of the first connection member 140 in the second direction D2. A volume of the second connection member 460 may be smaller than that of the first connection member 140.

In some embodiments, a size of the third connection member 560 may be smaller than that of the first connection member 140. For example, a width of the third connection member 560 in the first direction D1 is smaller than that of the first connection member 140 in the first direction D1. A volume of the third connection member 560 may be smaller than that of the first connection member 140.

Each of the second connection member 460 and the third connection member 560 may be a solder bump that includes a low melting point metal, for example, tin (Sn) and a tin (Sn) alloy, but is not limited thereto. Each of the second connection member 460 and the third connection member 560 may have various shapes such as a land, a ball, a pin, and a pillar. In addition, each of the second connection member 460 and the third connection member 560 may include under bump metallurgy (UBM).

Each of the second connection member 460 and the third connection member 560 may be formed as a single layer or multiple layers. When each of the second connection member 460 and the third connection member 560 is formed as a single layer, each of the second connection member 460 and the third connection member 560 may include a tin-silver (Sn—Ag) solder or copper (Cu), but is not limited thereto. When each of the second connection member 460 and the third connection member 560 is formed of multiple layers, each of the second connection member 460 and the third connection member 560 may include a copper (Cu) filler and a solder as an example, but the embodiments of the present disclosure are not limited thereto. Various modifications may be made in the number, interval, arrangement shape, etc. of each of the second connection members 460 and the third connection members 560 depending on the design without limitation to the illustrated example.

In some embodiments, a first underfill 450 may be formed between the second redistribution layer 300 and the first semiconductor chip 400. A second underfill 550 may be formed between the second redistribution layer 300 and the second semiconductor chip 500. The first underfill 450 may fill a space between the second redistribution layer 300 and the first semiconductor chip 400. The second underfill 550 may fill a space between the second redistribution layer 300 and the second semiconductor chip 500. In addition, the first underfill 450 may extend around (e.g., cover a side of) the second connection member 460. The second underfill 550 may extend around (e.g., cover a side of) the third connection member 560.

The first underfill 450 and the second underfill 550 may prevent the first and second semiconductor chips 400 and 500 from being broken by fixing the first and second semiconductor chips 400 and 500 onto the second redistribution layer 300. Each of the first underfill 450 and the second underfill 550 may include, for example, an insulating polymer material such as EMC, but is not limited thereto.

A mold layer 600 may be disposed on the second redistribution layer 300. The mold layer 600 may be provided between the first semiconductor chip 400 and the second semiconductor chip 500. The mold layer 600 may separate the first semiconductor chip 400 and the second semiconductor chip 500 from each other.

The mold layer 600 may include, for example, an insulating polymer material such as EMC, but is not limited thereto. The mold layer 600 may include a material different from that of the first underfill 450 and the second underfill 550. For example, each of the first underfill 450 and the second underfill 550 may include an insulating material having fluidity more excellent than that of the mold layer 600. Therefore, the first underfill 450 and the second underfill 550 may efficiently fill a narrow space between the second redistribution layer 300 and the first and second semiconductor chips 400 and 500.

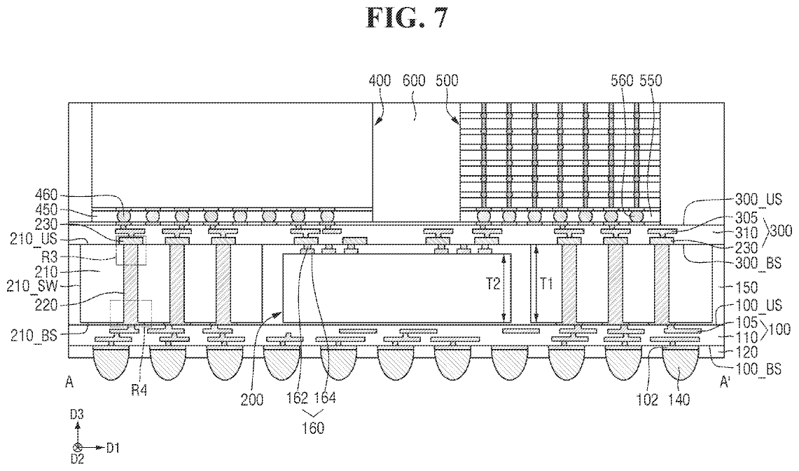

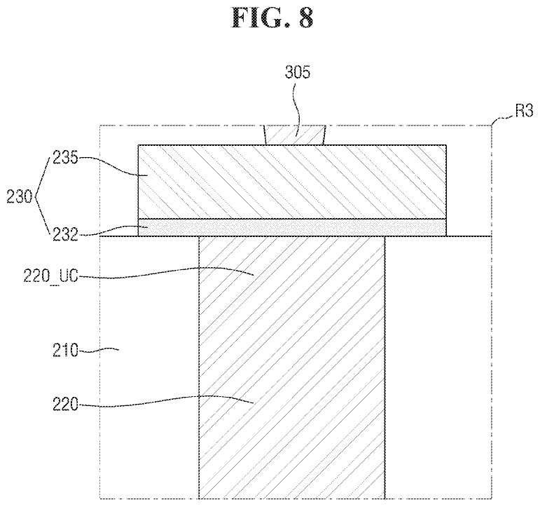

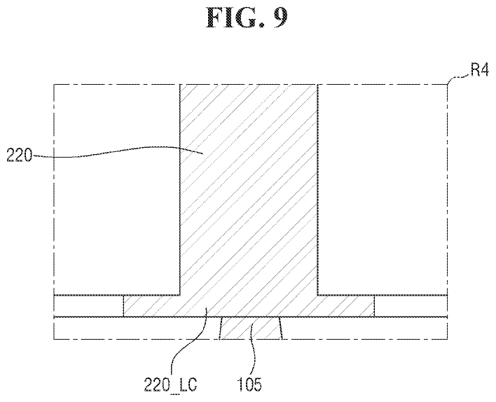

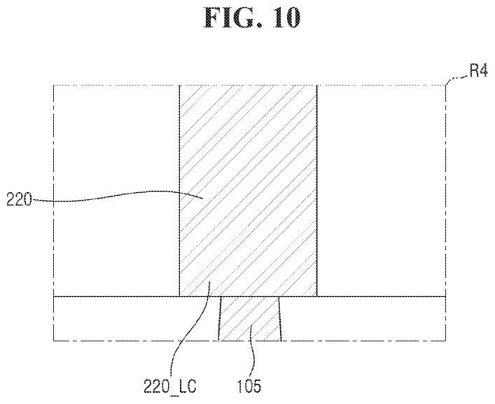

FIG. 7 is a cross-sectional view illustrating a semiconductor package according to some embodiments. FIG. 8 is an enlarged view illustrating a portion R3 of FIG. 7. FIGS. 9 and 10 are enlarged views illustrating a portion R4 of FIG. 7. For convenience of description, the following description will be based on differences from those described with reference to FIGS. 1 to 6.

Referring to FIGS. 7 to 10, a through via 220 may be formed in a through hole TH. The through via 220 may be formed along an inner wall (e.g., an inner sidewall) of the through hole TH. For example, the through via 220 may fill the through hole TH. The through via 220 may include a metal material such as copper (Cu) or aluminum (Al), but is not limited thereto. The following description will be based on that the through via 220 includes copper (Cu), but the embodiments of the present disclosure are not limited thereto.

An upper contact portion 220_UC of the through via 220 may be in contact with a via pad 230. As the inside of the through via 220 is filled with copper (Cu), a contact area between the through via 220 and the via pad 230 may be increased.

A shape of a lower contact portion 220_LC of the through via 220 may be different from that of the upper contact portion 220_UC. A width of the lower contact portion 220_LC in a direction parallel with the upper surface 100_US of the first redistribution layer 100 (e.g., the first direction D1) may be greater than that of the upper contact portion 220_UC. A first conductive pattern 105 may be connected (e.g., electrically connected) to the lower contact portion 220_LC. A portion of the first conductive pattern 105 may be connected to a central portion of the lower contact portion 220_LC. A portion of the first conductive pattern 105 may be disposed at one side out of the center of the lower contact portion 220_LC. That is, various modifications may be made in the arrangement of the first conductive pattern 105 that is in contact with the lower contact portion 220_LC.

Referring to FIG. 10, in some embodiments, the lower contact portion 220_LC of the through via 220 may have the same shape as that of the upper contact portion 220_UC. For example, the lower contact portion 220_LC and the upper contact portion 220_UC may compose the through via 220 as a unitary structure. The through via 220 may have a cylindrical shape. A portion of the first conductive pattern 105 may be connected (e.g., electrically connected) to the lower contact portion 220_LC of the through via 220 (e.g., a lower surface of the through via 220).

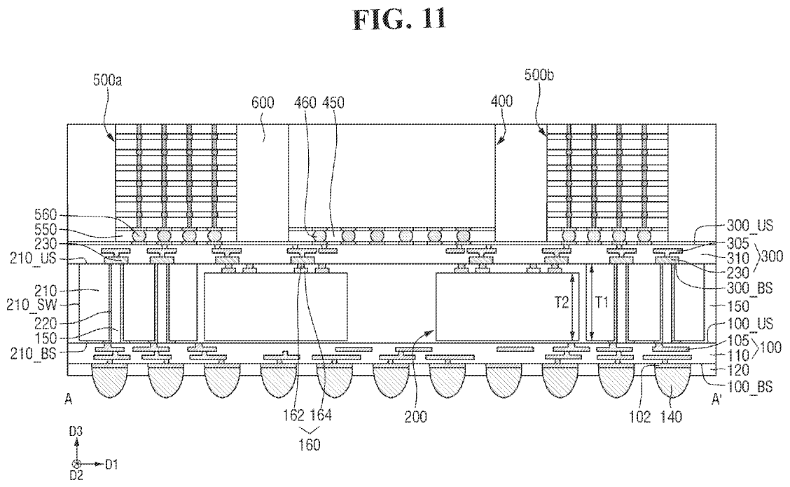

FIG. 11 is a cross-sectional view illustrating a semiconductor package according to some embodiments. For convenience of description, the following description will be based on differences from those described with reference to FIGS. 1 to 6.

Referring to FIG. 11, a semiconductor package 1000 may include a third semiconductor chip 500a and a fourth semiconductor chip 500b.

The third semiconductor chip 500a and the fourth semiconductor chip 500b may correspond to the second semiconductor chip 500 of FIG. 2. The description of the third semiconductor chip 500a and the fourth semiconductor chip 500b may be similar to that of the second semiconductor chip 500 in FIG. 2. The following description will be based on differences from FIG. 2.

The third semiconductor chip 500a and the fourth semiconductor chip 500b may be packaged on an upper surface 300_US of a second redistribution layer 300. The third semiconductor chip 500a may be disposed at one side of a first semiconductor chip 400. The fourth semiconductor chip 500b may be disposed at the other side of the first semiconductor chip 400. That is, the first semiconductor chip 400 may be disposed between the third semiconductor chip 500a and the fourth semiconductor chip 500b. A mold layer 600 may be disposed between the third semiconductor chip 500a and the first semiconductor chip 400 and between the fourth semiconductor chip 500b and the first semiconductor chip 400. The mold layer 600 may be on the first semiconductor chip 400, the third semiconductor chip 500a, and the fourth semiconductor chip 500b. The mold layer 600 may extend around (e.g., surround) the first semiconductor chip 400, the third semiconductor chip 500a and the fourth semiconductor chip 500b.

In some embodiments, a plurality of connection modules 200 may be provided. One of the plurality of connection modules 200 may electrically connect the first semiconductor chip 400 with the third semiconductor chip 500a through the second redistribution layer 300. The other one of the plurality of connection modules 200 may electrically connect the first semiconductor chip 400 with the fourth semiconductor chip 500b through the second redistribution layer 300.

In FIG. 11, the third semiconductor chip 500a and the fourth semiconductor chip 500b are illustrated as being disposed at both sides of the first semiconductor chip 400 one by one, but are not limited thereto. For example, a sum of the number of the third semiconductor chips 500a and the number of the fourth semiconductor chips 500b may be more than two.

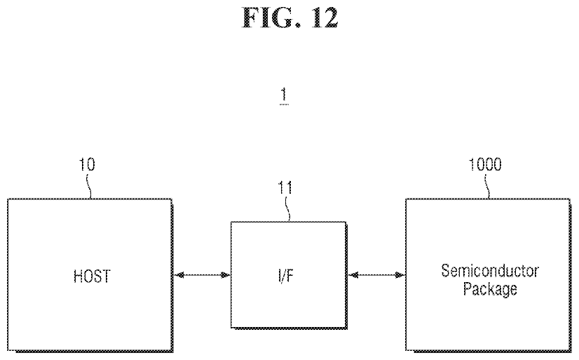

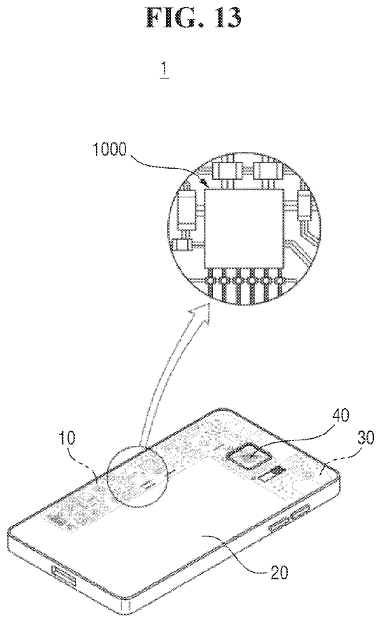

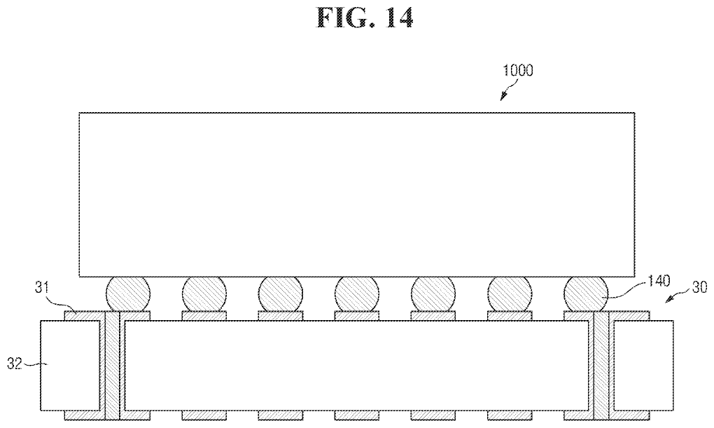

FIG. 12 is a view illustrating an electronic device according to some embodiments. FIG. 13 is a view illustrating an electronic device according to some embodiments. FIG. 14 is a cross-sectional view illustrating a semiconductor package and a main board of FIG. 13.

Referring to FIG. 12, an electronic device 1 may include a host 10, an interface 11 and a semiconductor package 1000. In FIGS. 12 to 14, the semiconductor package 1000 may be the semiconductor package 1000 of FIG. 1.

In some embodiments, the host 10 may be electrically connected with the semiconductor package 1000 through the interface 11. For example, the host 10 may transfer a signal to the semiconductor package 1000 to control the semiconductor package 1000. Also, for example, the host 10 may receive a signal from the semiconductor package 1000 to process data included in the signal.

For example, the host 10 may include a central processing unit (CPU), a controller, or an application specific integrated circuit (ASIC). In addition, for example, the host 10 may include a memory chip such as a dynamic random access memory (DRAM), a static RAM (SRAM), a phase-change RAM (PRAM), a magneto resistive RAM (MRAM), a ferroelectric RAM (FeRAM), and a resistive RAM (RRAM).

Referring to FIGS. 12 and 13, the electronic device 1 may include a host 10, a body 20, a main board 30, a camera module 40, and a semiconductor package 1000.

The main board 30 may be packaged in the body 20 of the electronic device 1. The host 10, the camera module 40, and the semiconductor package 1000 may be packaged on the main board 30. The host 10, the camera module 40, and the semiconductor package 1000 may be electrically connected to one another by the main board 30. For example, the interface 11 may be implemented by the main board 30.

The host 10 and the semiconductor package 1000 may be electrically connected to each other by the main board 30 to transmit and receive a signal to and from each other.

Referring to FIG. 14, the semiconductor package 1000 may be disposed on the main board 30. For example, the first connection member 140 may be disposed on the main board 30. The main board 30 may be connected (e.g., electrically connected) to the semiconductor package 1000 by the first connection member 140.

The main board 30 may be a printed circuit wiring structure (or printed circuit board (PCB)), a ceramic wiring structure, a glass wiring structure, or an interposer wiring structure, but the embodiments of the present disclosure are not limited thereto. For convenience of description, it is assumed that the main board 30 is a printed circuit wiring structure.

The main board 30 may include a connection structure 31 and a core 32. The core 32 may include, for example, a copper clad laminate (CCL), a Prepreg (PPG), an Ajinomoto Build-up Film (ABF), epoxy, polyimide, and/or the like. The connection structure 31 may include copper (Cu), aluminum (Al), silver (Ag), tin (Sn), gold (Au), nickel (Ni), lead (Pb), titanium (Ti), and/or their alloy, but is not limited thereto.

The core 32 may be disposed at the center of the main board 30, and the connection structure 31 may be disposed at upper and lower portions of the core 32. The connection structure 31 may be disposed to be exposed from upper and lower portions of the main board 30.

The connection structure 31 may be also disposed to extend through (e.g., pass through) the core 32. The connection structure 31 may electrically connect elements, which are in contact with the main board 30, with each other. For example, the connection structure 31 may electrically connect the semiconductor package 1000 with the host 10. The connection structure 31 may electrically connect the semiconductor package 1000 with the host 10 through the first connection member 140.

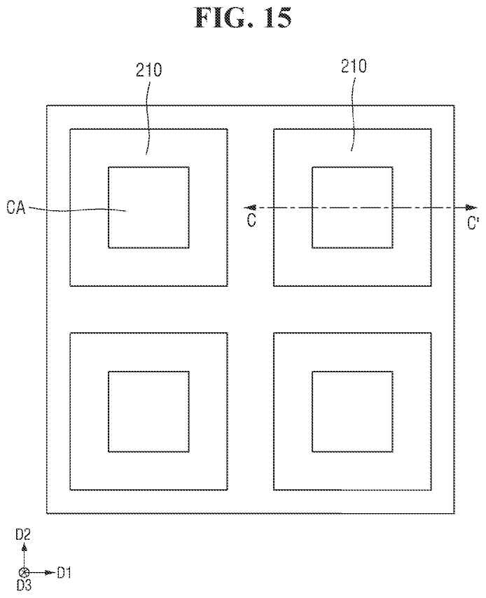

FIGS. 15 to 24 are views illustrating intermediate steps to describe a method of manufacturing a semiconductor package according to some embodiments. FIGS. 15 to 24 may be views illustrating a method of manufacturing the semiconductor package 1000 of FIG. 2. For reference, FIGS. 16 and 18 to 14 are cross-sectional views taken along line C-C′ of FIG. 15.

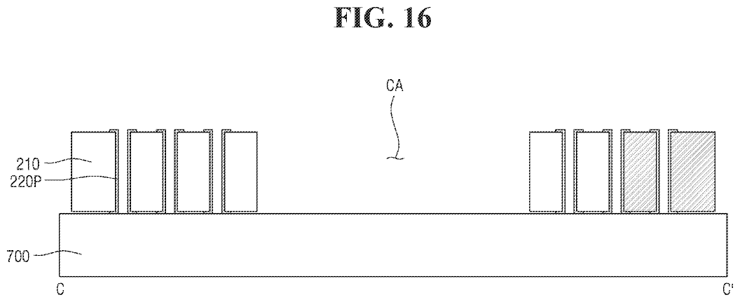

Referring to FIGS. 15 and 16, a plurality of glass cores 210 may be disposed on a substrate 700. The glass core 210 may be provided in a state that a through hole TH and a pre-through via 220P are formed therein.

The glass core 210 may be attached onto the substrate 700 through an adhesive. The glass core 210 may include a cavity CA therein. In FIG. 16, although one cavity CA is illustrated as being disposed at a central portion of the glass core 210, the embodiments of the present disclosure are not limited thereto. For example, the cavity CA may be disposed at one edge of the glass core 210. In addition, the cavity CA may be disposed at both edges of the glass core 210. Therefore, at least one cavity CA may be formed in the glass core 210.

The glass core 210 is illustrated as having a square shape in a plan view, but this is only an example embodiment. The glass core 210 may have a rectangular shape as shown in FIG. 1, and various modifications may be made in the shape of the glass core 210 depending on the design.

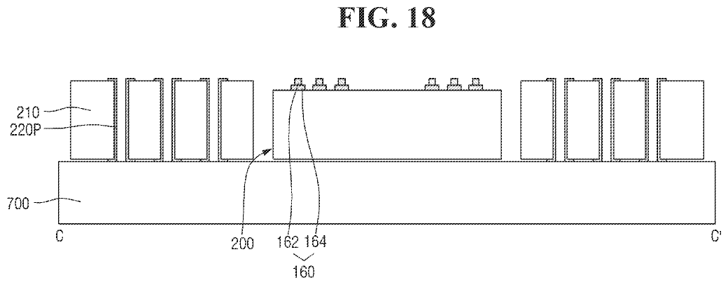

Referring to FIGS. 17 and 18, a connection module 200 may be disposed in each of cavities CA of the plurality of glass cores 210. The connection module 200 may be packaged on the substrate 700 by an adhesive. Subsequently, a first bump 160 may be formed on the connection module 200. In detail, a first pillar layer 164 and a first solder layer 162 may be sequentially formed. An upper surface of the first solder layer 162 may be disposed to be higher than an upper surface 210_US of the glass core 210.

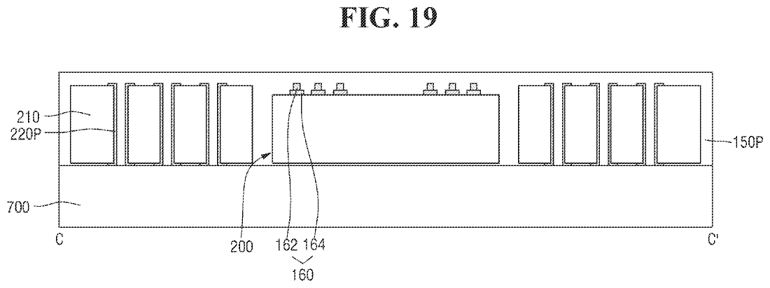

Referring to FIG. 19, a pre-second insulating layer 150P may be on (e.g., cover) the glass core 210 and the connection module 200 through an encapsulation process. The pre-second insulating layer 150P may be disposed in the through hole TH of the glass core 210 (e.g., disposed on an inner sidewall of the pre-through via 220P). For example, the pre-second insulating layer 150P may fill a remaining portion of the through hole TH in which the pre-through via 220P is formed.

The pre-second insulating layer 150P may include an epoxy resin and/or a polyimide resin, but is not limited thereto. The pre-second insulating layer 150P may fix the glass core 210 and the connection module 200 and protect the glass core 210 and the connection module 200 from impacts from the outside.

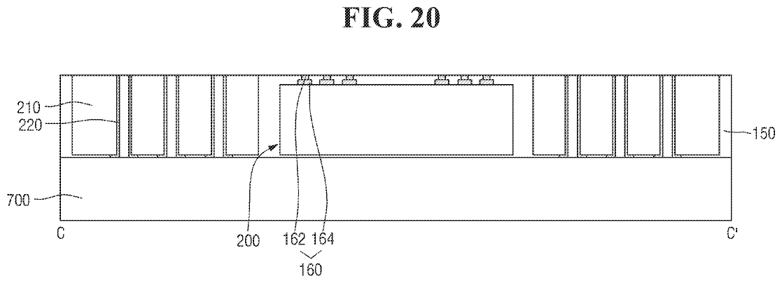

Referring to FIG. 20, the pre-second insulating layer 150P may be partially ground to form a second insulating layer 150. At this time, a portion of the pre-through via 220P may be removed to form the through via 220, and a portion of the first solder layer 162 may be removed. As the second insulating layer 150 is formed, (e.g., an upper surface of) the upper contact portion 220_UC of the through via 220 and (e.g., an upper surface of) the first solder layer 162 may be exposed.

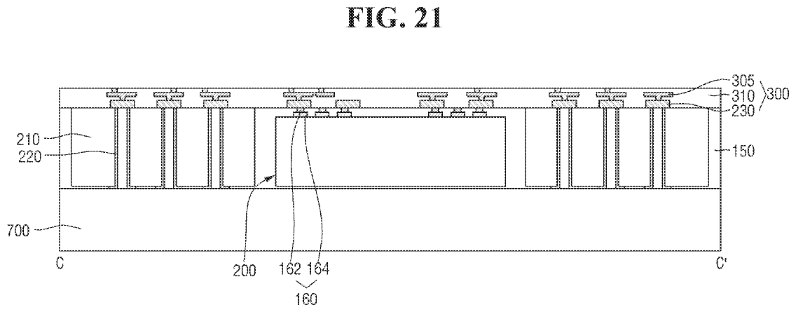

Referring to FIG. 21, a second redistribution layer 300 may be formed on the upper surface 210_US of the glass core 210. In detail, a via pad 230 connected (e.g., electrically connected) to the through via 220 and a second conductive pattern 315 connected (e.g., electrically connected) to the via pad 230 may be formed in a third insulating layer 310. The third insulating layer 310 may be formed, for example, by coating and curing a photosensitive resin (e.g., PID) on a carrier, and the via pad 230 and the second conductive pattern 305 may be formed using a photo process, an etching process, a plating process, or the like.

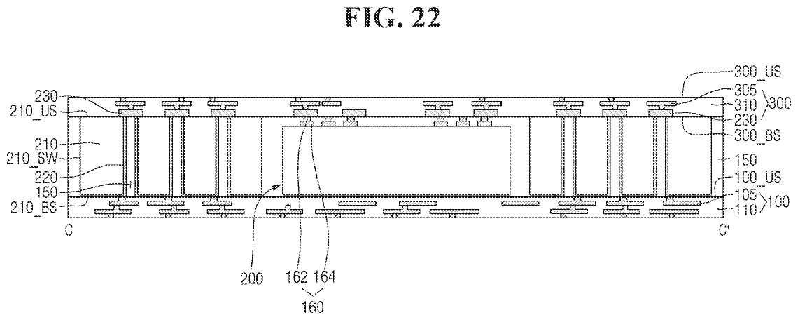

Referring to FIG. 22, the substrate 700 may be removed, and a first redistribution layer 100 may be formed on the position from which the substrate 700 is removed. The first redistribution layer 100 may include a first insulating layer 110 and a first conductive pattern 105 in the first insulating layer 110. The first insulating layer 110 may be formed, for example, by coating and curing a photosensitive resin (e.g., PID) on a carrier, and the first conductive pattern 105 may be formed using a photo process, an etching process, a plating process, or the like.

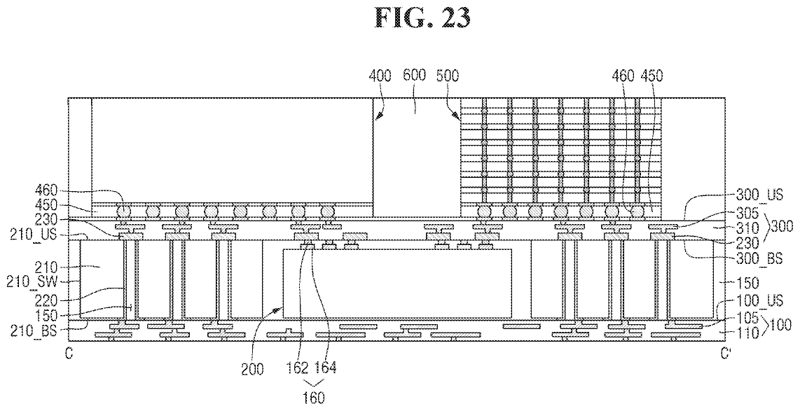

Referring to FIG. 23, a first semiconductor chip 400 and a second semiconductor chip 500 may be packaged on an upper surface 300_US of the second redistribution layer 300. The first semiconductor chip 400 may be packaged by a flip chip process. Subsequently, a mold layer 600 may be formed on the first semiconductor chip 400 and the second semiconductor chip 500.

Subsequently, a first lower passivation layer 120 and a first lower pad 102 may be formed on a lower surface 100_BS of the first redistribution layer 100. The first lower passivation layer 120 may be on (e.g., cover) the first redistribution layer 100 and expose a portion of the first lower pad 102. Subsequently, a first connection member 140 may be formed on the first lower pad 102. The first connection member 140 may be, for example, spherical or elliptical in a plan view, but is not limited thereto. The semiconductor package 1000 in which the first connection member 140 is formed may be the same as that of FIG. 2.

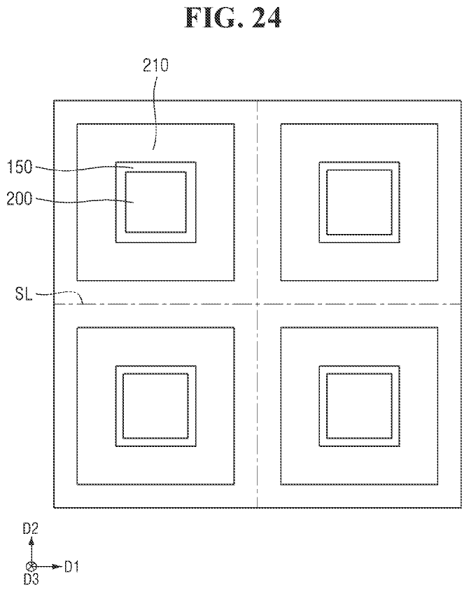

Next, referring to FIG. 24, a plurality of semiconductor packages 1000 may be separated into individual semiconductor packages 1000 through a dicing or sawing process along a cutting line SL.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, “coupled to”, or “in contact with” another element or layer, it may be directly on, connected to, coupled to, or in contact with the other element or layer, or one or more intervening elements or layers may be present. In contrast, when an element is referred to as being “directly coupled,” “directly connected,” or “directly responsive” to, “directly in contact with” or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor package comprising:
a first redistribution layer that includes a first insulating layer and a first conductive pattern in the first insulating layer;
a connection module on an upper surface of the first redistribution layer;
a glass core that extends around the connection module on the upper surface of the first redistribution layer;
a through via extended in the glass core;
a second insulating layer on the glass core, wherein a portion of the second insulating layer is in the through via;
a second redistribution layer on an upper surface of the glass core, wherein the second redistribution layer includes a third insulating layer, a second conductive pattern, and a via pad, and wherein the second conductive pattern and the via pad are in the third insulating layer; and
a first semiconductor chip and a second semiconductor chip on an upper surface of the second redistribution layer,
wherein the first semiconductor chip and the second semiconductor chip are spaced apart from each other,
wherein the via pad is in contact with the through via, and
wherein the first semiconductor chip and the second semiconductor chip are electrically connected to each other through the connection module.

2. The semiconductor package of claim 1, wherein the through via includes a lower contact portion and an upper contact portion,
wherein the lower contact portion is on a lower surface of the glass core,
wherein the lower surface of the glass core and the upper surface of the glass core are opposite to each other,
wherein the upper contact portion is in contact with the via pad, and
wherein a width of the lower contact portion in a horizontal direction parallel with the upper surface of the first redistribution layer is greater than a width of the upper contact portion in the horizontal direction.

3. The semiconductor package of claim 2, wherein the lower contact portion includes a first portion and a second portion,
wherein the first portion includes an area that is in contact with the first conductive pattern,
wherein the second portion is free of an area that is in contact with the first conductive pattern,
wherein the portion of the second insulating layer in the through via is between the first portion and the second portion in a cross-sectional view, and
wherein a width of the first portion in the horizontal direction is greater than a width of the second portion in the horizontal direction.

4. The semiconductor package of claim 2, wherein the upper contact portion is completely overlapped by the via pad in a vertical direction perpendicular to the upper surface of the first redistribution layer.

5. The semiconductor package of claim 2, wherein the width of the upper contact portion is about 60 micrometers (μm) or less in the horizontal direction.

6. The semiconductor package of claim 1, wherein the via pad includes a metal layer.

7. The semiconductor package of claim 1, wherein a thickness of the glass core in a vertical direction perpendicular to the upper surface of the first redistribution layer is greater than a thickness of the connection module in the vertical direction.

8. The semiconductor package of claim 7, wherein a difference between the thickness of the glass core and the thickness of the connection module is about 15 micrometers (μm) to about 30 μm.

9. The semiconductor package of claim 1, wherein a distance between an outer surface of the through via and an outer surface of the portion of the second insulating layer in the through via in a horizontal direction parallel with the upper surface of the first redistribution layer is about 20 micrometers (μm) or less.

10. The semiconductor package of claim 1, wherein the connection module includes silicon (Si).

11. The semiconductor package of claim 1, further comprising a first connection member on a lower surface of the first redistribution layer,
wherein the first connection member is electrically connected to a package substrate.

12. The semiconductor package of claim 1, further comprising a third semiconductor chip on the upper surface of the second redistribution layer,
wherein the connection module includes a first connection module and a second connection module,
wherein the first semiconductor chip and the second semiconductor chip are electrically connected to each other through the first connection module, and
wherein the first semiconductor chip and the third semiconductor chip are electrically connected to each other through the second connection module.

13. A semiconductor package comprising:
a first redistribution layer that includes a first insulating layer and a first conductive pattern in the first insulating layer;
a glass core on an upper surface of the first redistribution layer;
a connection module in the glass core;
a second insulating layer that extend around the glass core;
a second redistribution layer on an upper surface of the glass core, wherein the second redistribution layer includes a third insulating layer, a second conductive pattern, and a via pad, and wherein the second conductive pattern and the via pad are in the third insulating layer;
a through via that extends through the glass core in a vertical direction perpendicular to the upper surface of the first redistribution layer, wherein the first redistribution layer and the second redistribution layer are electrically connected to each other through the through via; and
a first semiconductor chip and a second semiconductor chip on an upper surface of the second redistribution layer and spaced apart from each other,
wherein the first semiconductor chip and the second semiconductor chip are electrically connected through the connection module,
wherein the through via includes a lower contact portion on a lower surface of the glass core and an upper contact portion that is in contact with the via pad, and
wherein a width of the lower contact portion in a horizontal direction parallel with the upper surface of the first redistribution layer is greater than a width of the upper contact portion in the horizontal direction.

14. The semiconductor package of claim 13, wherein the via pad includes a metal layer.

15. The semiconductor package of claim 13, wherein the through via includes a portion of the second insulating layer therein.

16. The semiconductor package of claim 13, wherein a width of the via pad in the horizontal direction is greater than the width of the upper contact portion in the horizontal direction.

17. The semiconductor package of claim 13, wherein the connection module includes silicon (Si).

18. The semiconductor package of claim 13, further comprising a first connection member on a lower surface of the first redistribution layer,
wherein the first connection member is electrically connected to a package substrate.

19. The semiconductor package of claim 13, further comprising a first bump between the connection module and the second redistribution layer, wherein the connection module and the second redistribution layer are electrically connected to each other through the first bump.

20. A semiconductor package comprising:
a first redistribution layer that includes a first insulating layer and a first conductive pattern in the first insulating layer;
a connection module on an upper surface of the first redistribution layer;
a glass core that extends around the connection module on the upper surface of the first redistribution layer, wherein the glass core includes a through via;
a second insulating layer that extend around the glass core, wherein a portion of the second insulating layer is inside the through via;
a second redistribution layer on an upper surface of the glass core, wherein the second redistribution layer includes a third insulating layer, a second conductive pattern, and a via pad, and wherein the second conductive pattern and the via pad are in the third insulating layer; and
a first semiconductor chip and a second semiconductor chip that are spaced apart from each other on an upper surface of the second redistribution layer,
wherein the via pad is in contact with an upper contact portion of the through via,
wherein the via pad includes a metal layer,
wherein the first semiconductor chip and the second semiconductor chip are electrically connected to each other through the connection module,
wherein the through via includes a lower contact portion that is electrically connected to the first conductive pattern, and
wherein a width of the lower contact portion in a horizontal direction parallel with the upper surface of the first redistribution layer is greater than a width of the upper contact portion in the horizontal direction.
